(19) United States
(12) Patent Application Publication
(10) Pub. No.: US 2024/0401705 A1
(43) Pub. Date: Dec. 5, 2024

(54) VALVE DEVICE, FLUID CONTROL DEVICE, FLUID CONTROL METHOD, SEMICONDUCTOR MANUFACTURING DEVICE, AND SEMICONDUCTOR MANUFACTURING METHOD

(71) Applicant: FUJIKIN INCORPORATED, Osaka-shi (JP)

(72) Inventors: Keisuke Ishibashi, Osaka-shi (JP); Tadayuki Yakushijin, Osaka-shi (JP); Tsuyoshi Tanikawa, Osaka-shi (JP)

(73) Assignee: FUJIKIN INCORPORATED, Osaka-shi (JP)

(21) Appl. No.: 18/692,504

(22) PCT Filed: Jun. 30, 2022
(86) PCT No.: PCT/JP2022/026255

§ 371 Date: Mar. 15, 2024

(30) Foreign Application Priority Data
Sep. 27, 2021 (JP) 2021-156480

(51) Int. Cl. F16K 1/52; F16K 1/36; H01L 21/67

(52) U.S. Cl. CPC F16K 1/52; F16K 1/36; H01L 21/67017

(57) ABSTRACT

An object of the invention is to provide a valve device and the like including an inner disk that can be easily assembled, in which a Cv value is guaranteed and the inner disk is provided under a lower risk of being damaged. The valve device includes a valve body including first flow path, and a valve chamber; an inner disk including an inner side annular portion that is disposed in a periphery of a first opening, an outer side annular portion, and a connection portion; a diaphragm coming into contact with and separated from an annular upper side seat provided at an upper end portion of the inner side annular portion to cause interruption and communication between the flow paths; and an annular lower side seat that is provided at a lower end portion of the inner side annular portion.

### TECHNICAL FIELD

The present invention relates to a valve device, a fluid control device, a fluid control method, a semiconductor manufacturing device, and a semiconductor manufacturing method.

### BACKGROUND ART

For example, in a semiconductor manufacturing process, a valve device that controls supplying of various process gasses is used for a chamber of a semiconductor manufacturing device. The invention described in PTL 1 mainly relates to a metal diaphragm valve of a direct touch type, used for a gas supply system and the like of a semiconductor manufacturing facility. As illustrated in FIG. 9, a valve body 101 of a metal diaphragm valve 100 includes a fluid inlet 110, a fluid outlet 111, a valve seat 113, and a metal diaphragm 102. The valve seat 113 is provided in an annular groove formed in the valve body 101. A fluid flows in through the fluid inlet 110, flows through a valve chamber 112 from the lower surface side of the metal diaphragm 102, and flows out through the fluid outlet 111.

The invention described in PTL 2 mainly relates to a diaphragm valve used for gas supply system and the like of a semiconductor manufacturing facility, as does PTL 1. As illustrated in FIG. 10, a valve body 202 of a valve device 200 includes a first flow path 221, a second flow path 222, and a valve chamber 223. The valve chamber 223 is provided with an inner disk 203 including an inner side annular portion 232 and an outer side annular portion 231. The inner side annular portion 232 has an upper end portion provided with a valve seat 248 that comes into contact with/is separated from a diaphragm 241. The inner side annular portion 232 has a lower end portion provided with a disk seal 249 that comes into close contact with the bottom surface of the valve chamber 223.

The valve device 200 described in PTL 2 includes the inner disk 203 that is replaceable and not provided in the metal diaphragm valve 100 described in PTL 1, meaning that the valve body 202 needs no groove where the valve seat 113 is disposed as in the metal diaphragm valve 100 described in PTL 1, and thus is advantageous in terms of easy processing. Furthermore, while the metal diaphragm valve 100 described in PTL 1 requires an additional process or the like to be performed on the valve body 101 for the replacement and the like of the valve seat 113 or the like that has worn, the valve device 200 described in PTL 2 enables the inner disk 203 to be taken out for repair/replacement, and thus is advantageous in terms of easy maintenance.

Still furthermore, the valve chamber 223 of the valve device 200 described in PTL 2 is formed to be deeper in the vertical direction than the valve chamber 112 of the metal diaphragm valve 100 described in PTL 1. With this difference, the valve device 200 described in PTL 2 can process a large amount of fluid.

### CITATION LIST

### Patent Literature

PTL 1: JP2012-026577A
PTL 2: WO2019/193978

### SUMMARY OF INVENTION

### Technical Problem

The valve device 200 of PTL 2 in FIG. 10 has the following structure. Specifically, a bonnet 205 is screwed into a screw hole 225 to press a press adapter 243 from the above. As a result, the press adapter 243 presses the circumference edge of the diaphragm 241 from the above, and the circumference edge of the diaphragm 241 presses the outer side annular portion 231 from the above. The pressing force is transmitted to the inner side annular portion 232, and thus the disk seal 249 is crushed from the above by the bottom surface of the valve chamber 223, whereby the inner disk 203 is disposed at a predetermined position.

However, there has been a problem in that the disk seal 249 fails to be sufficiently crushed even when the bonnet 205 is screwed, resulting in a failure to move the inner disk 203 down to the design position, because the close contact between the bottom surface of the disk seal 249 and the bottom surface of the valve chamber 223 in the valve device 200 of PTL 2 is close contact between flat surfaces. The failure to move the inner disk 203 down to the design position leads to a small gap between the valve seat 248 and the diaphragm 241, resulting in a problematically small Cv value. This Cv value is an index indicating how efficiently a fluid such as gas can flow through an on-off valve.

The inner side annular portion 232 receives upward resilience force from the disk seal 249, and the outer side annular portion 231 receives downward force from the bonnet 205. Thus, a portion connecting the inner side annular portion 232 and the outer side annular portion 231 may receive excessively large force to be damaged. To prevent the damage, the diameter of a hole open in this connection portion can be made small, but this in turn leads to another problem in that the Cv value becomes small.

The invention is made in view of such a point, and an object of the invention is to provide a valve device and the like including an inner disk that can be easily assembled at a predetermined position, whereby a sufficient Cv value is guaranteed and the inner disk is provided under a lower risk of being damaged.

### Solution to Problem

The present invention (1) relates to a valve device including: a valve body forming a first flow path and a second flow path that are fluid passages and a valve chamber that communicates with the first flow path and the second flow path; an inner disk including an inner side annular portion that is disposed in a periphery of a first opening opened in the valve chamber at an edge end of the first flow path, an outer side annular portion that is disposed on an outer circumference side of the inner side annular portion, and a connection portion that has a plurality of second openings that communicate with the second flow path and connects the inner side annular portion with the outer side annular portion; a diaphragm coming into contact with and separated from an annular upper side seat provided at an upper end portion of the inner side annular portion to cause interruption and communication between the first flow path and the second flow path, the diaphragm having a lower surface circumference edge portion that comes into contact with an upper surface of the outer side annular portion, the diaphragm having an upper surface circumference edge portion pressed downwardly by a press adapter to make the diaphragm disposed under pressure; and an annular lower side seat provided at a lower end portion of the inner side annular portion and coming into close contact with a valve chamber bottom surface that is a bottom surface of the valve chamber, in which an annular valve chamber bottom surface protruding portion that is an upwardly protruding circumference edge portion of the valve chamber bottom surface on the first opening side comes into close contact with a part of a lower side seat lower end surface that is a lower end surface of the lower side seat.

According to the present invention (1), the annular valve chamber bottom surface protruding portion is provided that is the upwardly protruding circumference edge portion of the valve chamber bottom surface on the first opening side, and this valve chamber bottom surface protruding portion comes into close contact with a part of the lower side seat lower end surface that is the lower end surface of the lower side seat. Thus, the lower side seat lower end surface receiving the downward pressing force has a reduced area and its crushing as a result of plastic deformation is facilitated, whereby the inner disk can be easily assembled at a predetermined position. As a result, a valve device can be obtained in which a sufficient Cv value is guaranteed with a gap provided as designed between a valve seat and the diaphragm and the inner disk is provided under a lower risk of being damaged.

The present invention (2) relates to the valve device of the present invention (1), in which the lower side seat is held in a lower side seat accommodating groove formed in an end surface of the inner side annular portion on the valve body side.

According to the present invention (2), the lower side seat is held in the lower side seat accommodating groove formed in the end surface of the inner side annular portion on the valve body side. Thus, the lower side seat can be easily held in the inner side annular portion.

The present invention (3) relates to the valve device of the present invention (1) or the present invention (2), in which a gap to accommodate a bulging portion of the lower side seat made when the diaphragm is disposed under pressure by the press adapter is provided between an upper surface of the valve chamber bottom surface protruding portion and a lower end surface of the inner side annular portion.

According to the present invention (3), the gap to accommodate the bulging portion of the lower side seat made when the diaphragm is disposed under pressure by the press adapter is provided between the upper surface of the valve chamber bottom surface protruding portion and the lower end surface of the inner side annular portion. Thus, the crushing of the lower side seat is further facilitated, whereby the inner disk can be more easily assembled at the predetermined position, and a valve device can be obtained in which a sufficient Cv value is better guaranteed and the inner disk is provided under a lower risk of being damaged.

The present invention (4) relates to a fluid control device including a plurality of fluid devices arranged from an upstream side to a downstream side, characterized in that the plurality of fluid devices include the valve device of any one of the present invention (1) to the present invention (3).

The present invention (5) relates to a flow rate control method using the valve device of any one of the present invention (1) to the present invention (3) for adjusting a flow rate of a fluid.

The present invention (6) relates to a semiconductor manufacturing device using the valve device of any one of the present invention (1) to the present invention (3) for controlling a process gas in a process for manufacturing a semiconductor device that requires a processing step using the process gas in a closed chamber.

The present invention (7) relates to a semiconductor manufacturing method using the valve device of any one of the present invention (1) to the present invention (3) for controlling a flow rate of a process gas in a process for manufacturing a semiconductor device that requires a processing step using the process gas in a closed chamber.

### Advantageous Effects of Invention

The invention can provide a valve device and the like including an inner disk that can be easily assembled at a predetermined position, whereby a sufficient Cv value is guaranteed and the inner disk is provided under a lower risk of being damaged.

### BRIEF DESCRIPTION OF DRAWINGS

FIG. 1 is a partial cross-sectional view of a valve device according to an embodiment of the invention.

FIG. 2 is a diagram schematically illustrating differences among valve bodies of PTL 1 (A), PTL 2 (B), and the invention of the present application (C).

FIG. 3 is a perspective view of an inner disk.

FIG. 4 is a partial cross-sectional view of a lower end portion of an inner side annular portion.

FIG. 5 is a partial cross-sectional view of the lower end portion of the inner side annular portion to which a lower side seat is attached, in a state where the inner disk is disposed at a predetermined position.

FIG. 6 is a photograph of a cross section of the lower end portion of the inner side annular portion to which the lower side seat is attached, in the state where the inner disk is disposed at the predetermined position.

FIG. 7 is a schematic view illustrating an example where the valve device according to one embodiment of the invention is applied to a semiconductor manufacturing process.

FIG. 8 is a perspective view illustrating an example of a fluid control device using the valve device of the present embodiment.

FIG. 9 is a partial cross-sectional view of a metal diaphragm valve of PTL 1.

FIG. 10 is a partial cross-sectional view of the valve device of PTL 2.

### DESCRIPTION OF EMBODIMENTS

An embodiment of the invention will be described in detail below based on the drawings. The following embodiment is an essentially preferable example, and is not intended to limit the scope of the invention, the applications of the same, or the purposes of the same.

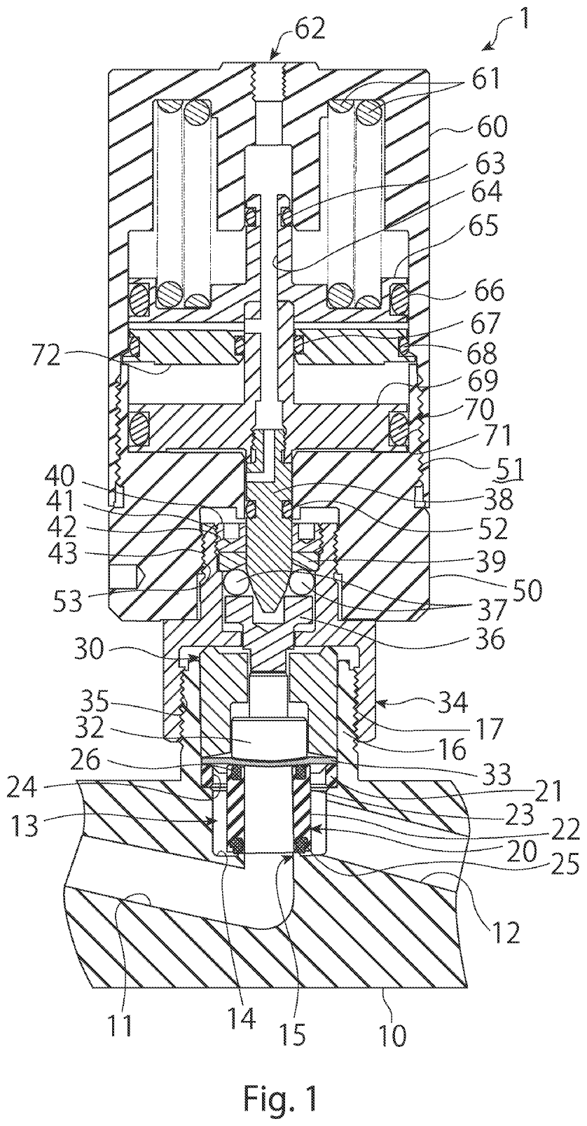

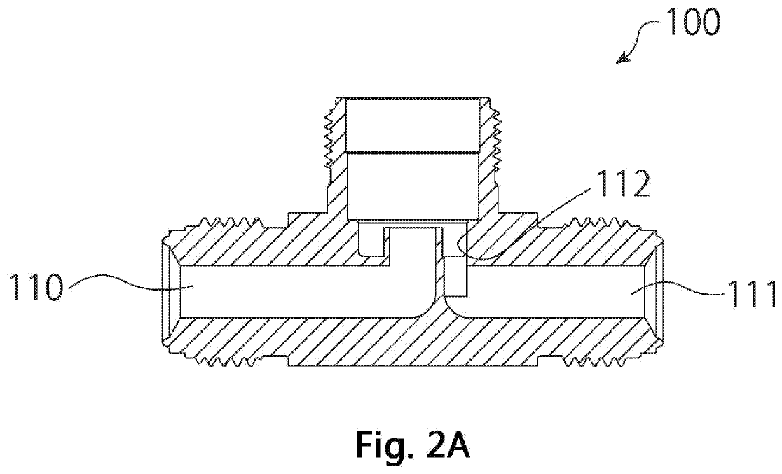

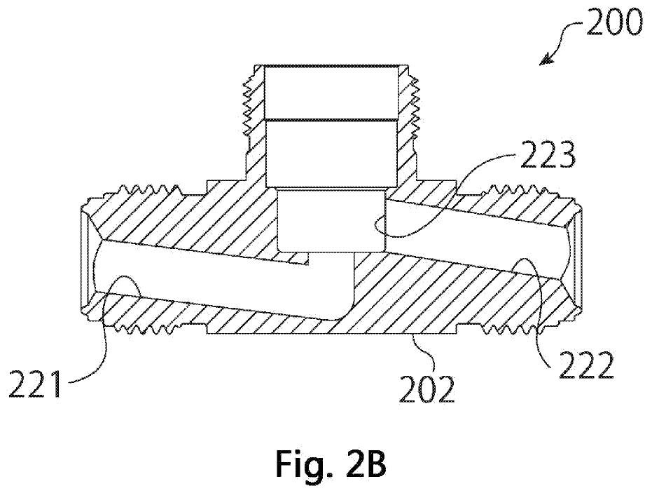

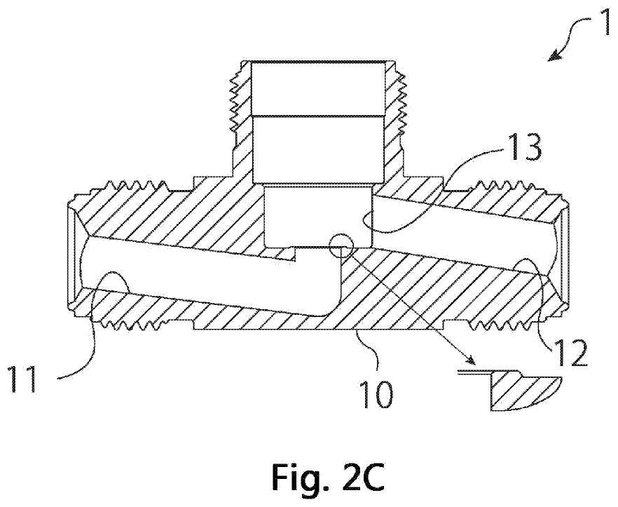

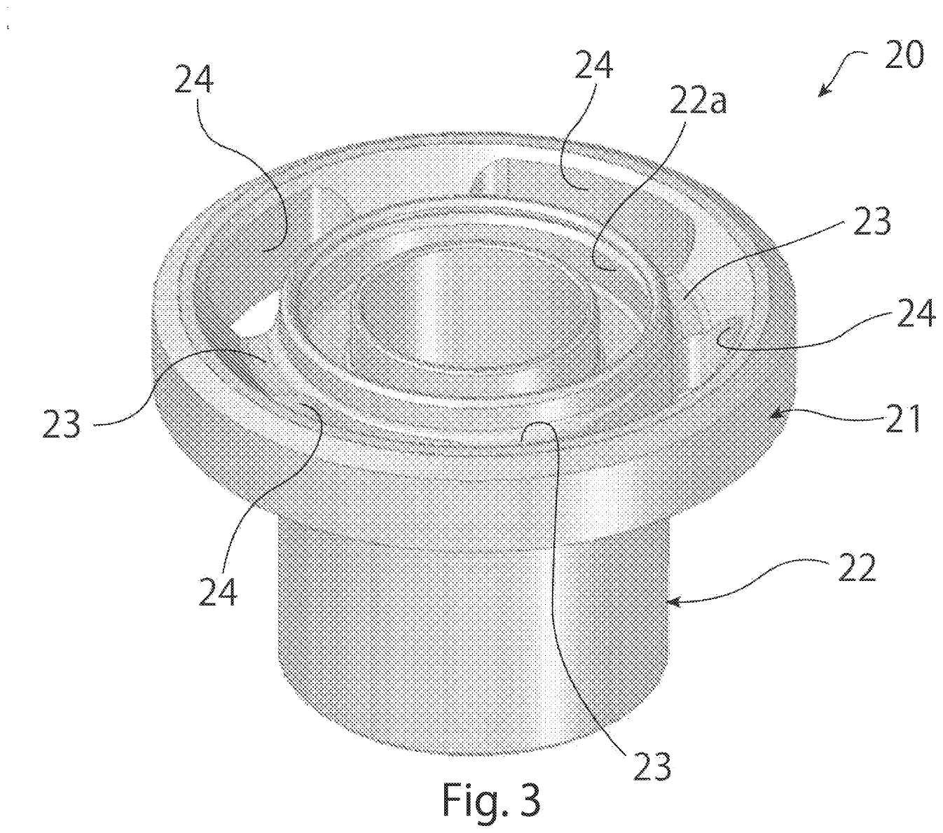

While FIG. 1 is a partial cross-sectional view of a valve device according to an embodiment of the invention, the description is made with reference to FIG. 2 and FIG. 3, before the description on this valve device. FIG. 2 is a diagram schematically illustrating differences among valve bodies of PTL 1 (A), PTL 2 (B), and the invention of the present application (C). The description will be given on the differences among the valve bodies.

FIG. 2(A) illustrates the valve body 101 of the metal diaphragm 100 of PTL 1. The fluid inlet 110 and the fluid outlet 111 communicate with each other through the valve chamber 112. FIG. 2(B) illustrates the valve body 202 of the valve device 200 of PTL 2. The first flow path 221 and the second flow path 222 communicate with each other through the valve chamber 223. The valve chamber 223 in FIG. 2(B) is expanded in the vertical direction as compared with the valve chamber 112 in FIG. 2(A). In FIG. 2(A), the passage of the fluid outlet 111 extends upward to communicate with the valve chamber 112, whereas in FIG. 2(B), the second flow path 222 extends in a lateral direction to directly communicate with the valve chamber 223. With such a difference in structure, the valve device 200 allows a larger amount of fluid to flow and can achieve a larger Cv value, than the metal diaphragm 100 does.

A valve body 10 according to one embodiment of the invention of the present application is illustrated in a valve device 1 in FIG. 2(C). A first flow path 11, a second flow path 12, and a valve chamber 13 are formed therein. FIG. 2(C) is different from FIG. 2(B) in the following point. Specifically, while the valve chamber 223 in FIG. 2(B) has a flat bottom surface, the bottom surface of the valve chamber 13 protrudes in a periphery of the opening of the first flow path 11 in FIG. 2(C). This is one featured part of the invention of the present application.

FIG. 3 is a perspective view of an inner disk 20. The inner disk 20 is disposed in the valve chamber 13. The inner disk 20 includes an outer side annular portion 21, an inner side annular portion 22, and a connection portion 23 connecting the outer side annular portion 21 and the inner side annular portion 22 to each other. An upper side seat accommodating groove 22a that accommodates an upper side seat 26 (see FIG. 1) is formed in an upper end portion of the inner side annular portion 22. Four second openings 24 are formed in the outer side annular portion 21. A fluid flows out to a second flow path 12 (see FIG. 1) through the second openings 24.

Next, the entirety of the valve device 1 in FIG. 1 will be described. The valve body 10 is formed to have the first flow path 11, the second flow path 12, and the valve chamber 13, and has, in an upper portion, a bonnet portion 16 with an inner recess. The inner disk 20 described above with reference to FIG. 3 is disposed in the valve chamber 13. The inner side annular portion 22 has an upper portion and a lower portion respectively provided with the upper side seat 26 and a lower side seat 25, and the lower side seat 25 is in close contact with a valve chamber bottom surface 14. A first opening 15 communicating with the valve chamber 13 is formed in the valve chamber bottom surface 14. After the inner disk 20 is disposed, the fluid enters the inner side annular portion 22 through the first opening 15. The second openings 24 are formed in the connection portion 23. A diaphragm 33 pressed by a press adapter 30 is disposed on the upper side seat 26.

An actuator including, as a casing, a lower side casing 50 and an upper side casing 60 is disposed above the bonnet 16. The actuator includes a spring coil 61, a first piston 65, a bulk head 72, a second piston 69, and a stem 38. Operation gas introduced through an operation gas supply port 62 flows through an operation gas passage 64 to move the stem 38 upward and downward. The upper side casing 60 and the lower side casing 50 are connected to each other through screwing between an upper side casing lower portion female screw 71 and a lower side casing male screw 51. Multiple O rings 63, 66, 67, 68, 70, and 52 are disposed to maintain airtightness.

A stroke increasing mechanism including a lid 40, a taper ring 39, and a ball 37 is provided in a lower portion recess of the lower side casing 50. The valve body 10 and the actuator are connected to each other via a nut 34. A nut lower portion female screw 35 and a bonnet portion upper portion male screw 17 are screwed to each other. A bonnet upper portion male screw 43 and a lower portion casing female screw 53 are screwed to each other. With the nut 34 screwed, the press adapter 30 presses the circumference edge of the diaphragm 33, whereby the diaphragm 33 is fixed between the press adapter 30 and the outer side annular portion 21. A lid male screw 41 and a nut upper portion female screw 42 are screwed to each other.

A tapered distal end portion of the stem 38 presses a disk 36 downward, and the disk 36 presses a diaphragm presser 32 downward. The diaphragm 33 thus pressed is deformed to be in contact with the upper side seat 26, whereby a flow of the fluid is interrupted. An upward movement of the stem 38 makes an opening through which the fluid flows.

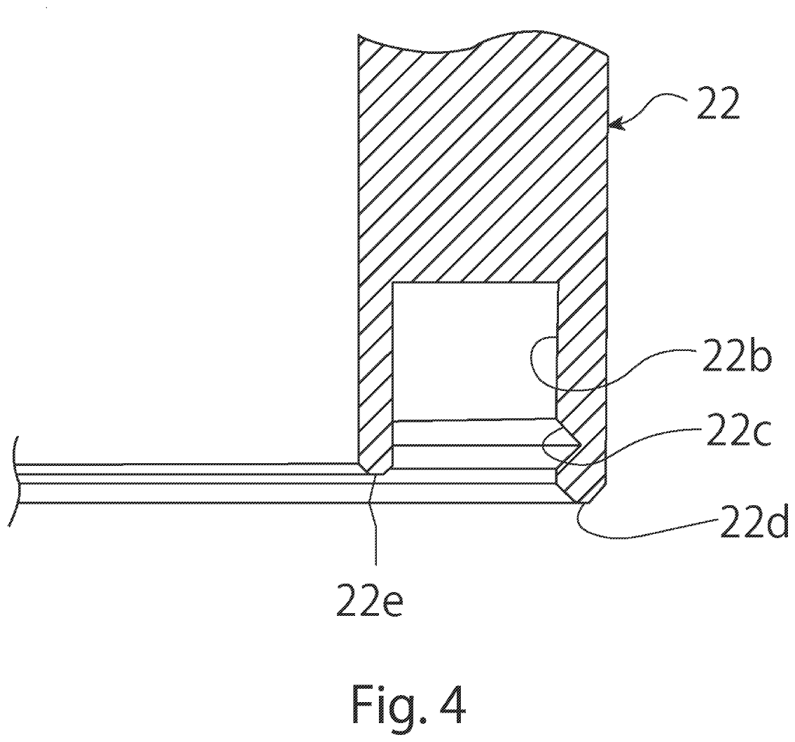

FIG. 4 is a partial cross-sectional view of a lower end portion of the inner side annular portion 22. An annular lower side seat accommodating groove 22b that holds the lower side seat 25 is formed in the lower end surface. An outer side lower end surface 22d that is the lower end surface of the lower side seat accommodating groove 22b on the outer side is positioned below an inner side lower end surface 22e that is the lower end surface on the inner side. This is because the outer circumference side lower end portion of the inner side annular portion 22 is folded toward the inner side using a notch 22c for inward caulking from the outer circumference side of the inner side annular portion 22 after the lower side seat 25 has been inserted, to prevent the lower side seat 25 from falling off. The upper end portion of the inner side annular portion 22 has substantially the same structure as the lower end portion, and the upper side seat 26 is fixed to the upper side seat accommodating groove through caulking.

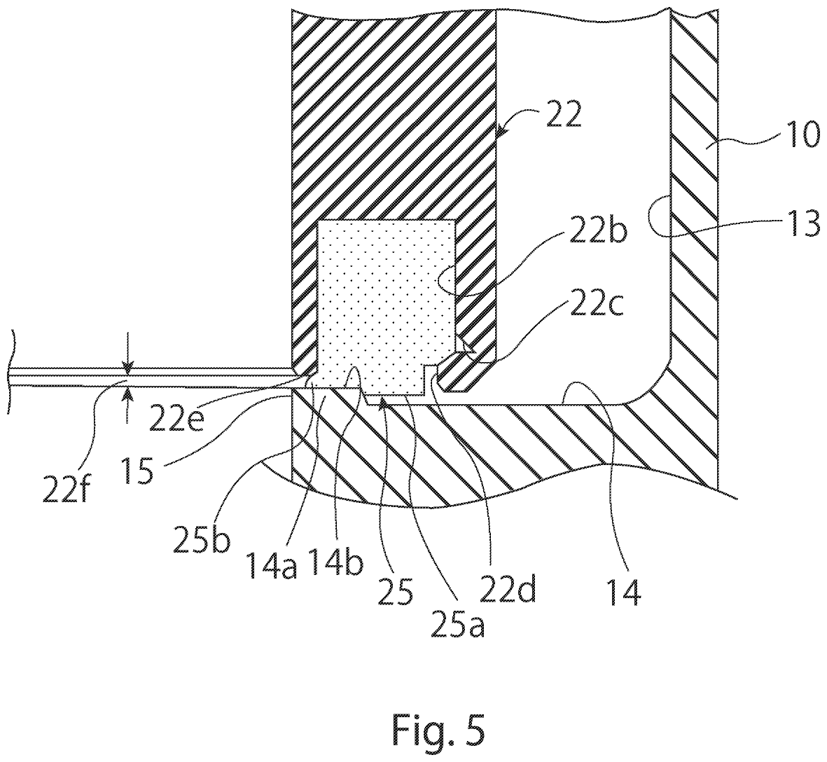

FIG. 5 is a partial cross-sectional view of the lower end portion of the inner side annular portion 22 to which the lower side seat 25 is attached, in a state where the inner disk 20 is disposed at a predetermined position. The outer circumference side lower end portion of the inner side annular portion 22 is inwardly caulked using the notch 22c. The downward pressing force from the press adapter 30 (see FIG. 1) causes the lower side seat 25 to come into contact with a valve chamber bottom surface protruding portion upper surface 14b that is the upper surface of a valve chamber bottom surface protruding portion 14a on the first opening 15 side opened in the valve chamber bottom surface 14 of the valve chamber 13 formed in the valve body 10. Thus, as illustrated, a lower side seat lower end surface 25a, which is originally flat, is crushed with a step formed, whereby the inner disk 20 is easily disposed at the predetermined position. With the inner disk 20 easily disposed at the predetermined position, a valve device is obtained in which a sufficient Cv value is guaranteed and the inner disk is provided under a lower risk of being damaged.

A gap 22f is provided between the inner side lower end surface 22e and the valve chamber bottom surface protruding portion upper surface 14b. An inner side bulging portion 25b bulged as a result of plastic deformation enters this gap 22f, whereby the crushing of the lower side seat 25 is further facilitated. Thus, the inner disk 20 can be more easily assembled at the predetermined position, whereby the valve device 1 can be obtained in which a sufficient Cv value is better guaranteed and the inner disk 20 is provided under a lower risk of being damaged.

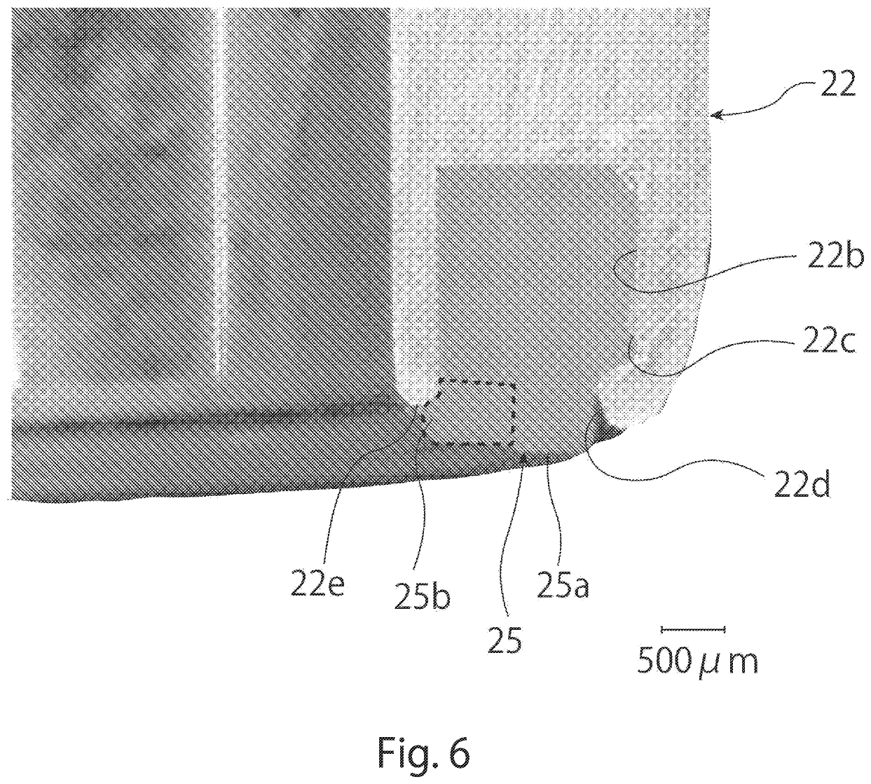

FIG. 6 is a photograph of an actual cross section of the lower end portion of the inner side annular portion 22 to which the lower side seat 25 is attached, in a state where the inner disk 20 is disposed at the predetermined position. It can be clearly seen that a step is formed at a boundary between portions of the lower side seat lower end surface 25a pressed and not pressed. Furthermore, it can be clearly seen that the inner side bulging portion 25b is formed with the first opening 15 (see FIG. 1) side of the lower side seat 25 bulged. While the bulging (material flow) of the lower side seat 25 occurs on the inner side of the lower side seat 25 because the contact portion between the valve chamber bottom surface protruding portion upper surface 14b and the lower side seat 25 is on the inner side, when the valve chamber bottom surface protruding portion upper surface 14b is formed more on the outer side than in the example illustrated, the contact portion is on the outer side of the lower side seat 25, and thus the bulging portion is also formed on the outer side.

A synthetic resin such as, for example, PFA, PA, PI, or PCTFE is used for the lower side seat 25. The resin involves a phenomenon in which deformation progresses with time when a large load continues to be applied, and may finally result in breaking. A portion surrounded by a dotted line in FIG. 6 is a large load region, and no load is applied to an outer side portion of the lower side seat 25. Thus, the creep phenomenon is less likely to occur in the outer side portion receiving no load, whereby the progress of the creep deformation stops at the outer side portion, so that the lower side seat 25 can be prevented from breaking. Without the valve chamber bottom surface protruding portion 14a, the lower side seat lower end surface 25a is entirely flat, meaning that the creep deformation also occurs on the outer side of the lower side seat 25, which is highly likely to finally result in rupturing.

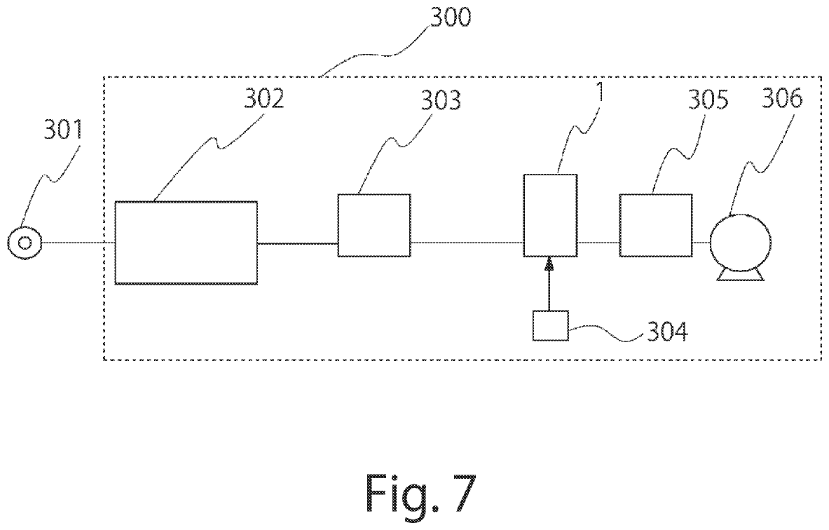

FIG. 7 is a schematic view illustrating an example where the valve device according to one embodiment of the invention is applied to a semiconductor manufacturing process. The application example of the valve device 1 will be described. A semiconductor manufacturing device 300 illustrated in FIG. 7 is a device that implements an ALD-based semiconductor manufacturing process. Here, 301 denotes a process gas supply source, 302 denotes a gas box, 303 denotes a tank, 304 denotes a control unit, 305 denotes a process chamber, and 306 denotes an exhaust pump. The ALD-based semiconductor manufacturing process requires precise adjustment of the flow rate of a process gas, and also requires a certain level of flow rate of the process gas through an increased diameter of the substrate. The gas box 302 is an integrated gas system (fluid control device) in which various fluid control devices such as an on-off valve, a regulator, and a mass flow controller are integrated and accommodated in a box, for supplying a precisely measured amount of process gas to the process chamber 305.

The tank 303 functions as a buffer that temporarily stores the process gas supplied from the gas box 302. The control unit 304 executes flow rate adjustment control, by controlling the supply of the operation gas to the valve device 1. The process chamber 305 provides a closed processing space for forming a film on a substrate by ALD. The exhaust pump 306 vacuums the inside of the process chamber 305. With such a system configuration, initial adjustment of the process gas can be performed by issuing an instruction for the flow rate adjustment from the control unit 304 to the valve device 1.

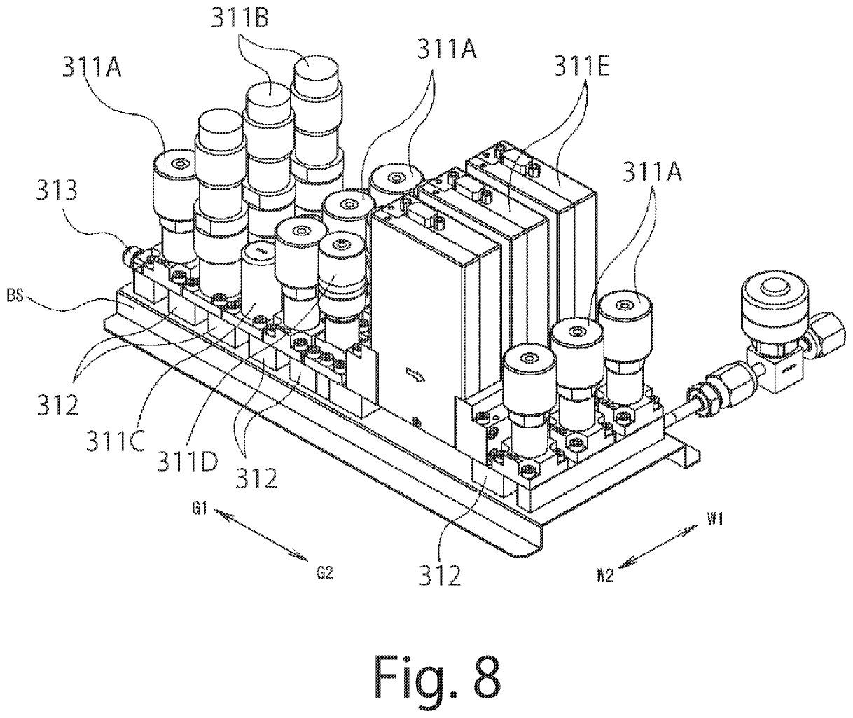

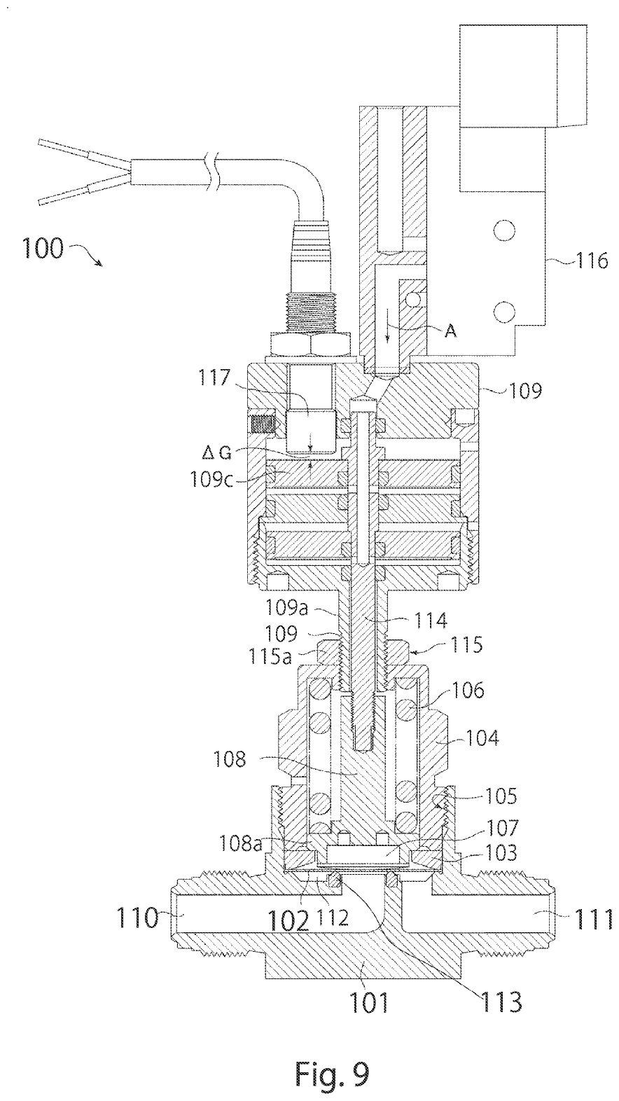

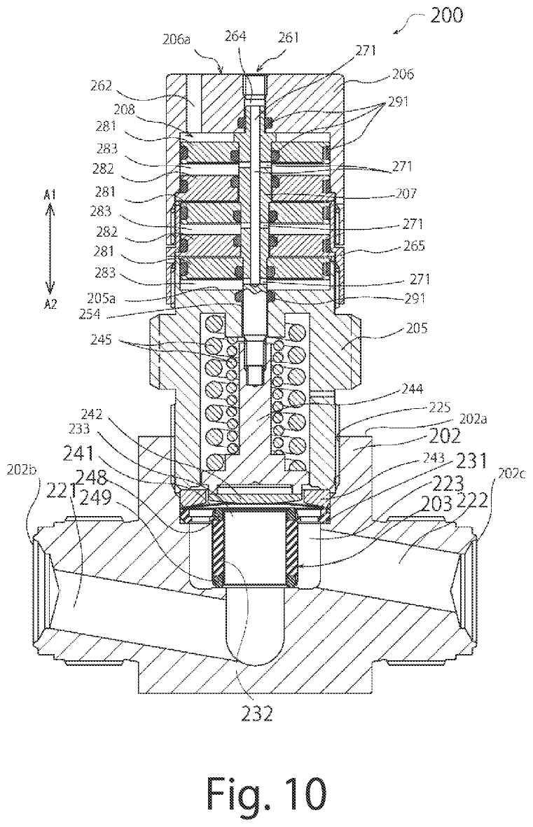

FIG. 8 is a perspective view illustrating an example of a fluid control device using the valve device of the present embodiment. An example of the fluid control device to which the invention is applied will be described. The fluid control device illustrated in FIG. 8 is provided with a metal base plate BS that is arranged along width directions W1 and W2 and extends in longitudinal directions G1 and G2. Note that W1 indicates the forward side direction, W2 indicates the back side direction, G1 indicates the upstream side direction, and G2 indicates the downstream side direction. Various fluid devices 311A to 311E are provided to the base plate BS via a plurality of flow path blocks 312. The plurality of flow path blocks 312 each form an unillustrated flow path through which the fluid flows from the upstream side G1 toward the downstream side G2.

Here, the “fluid device” is a device that is used for the fluid control device that controls the flow of the fluid, and includes a body defining a fluid flow path and has at least two flow path ports opened in a surface of the body. Specifically, an on-off valve (two-way valve) 311A, a regulator 311B, a pressure gauge 311C, an on-off valve (three-way valve) 311D, a mass flow controller 311E, and the like are provided without limitation. An introduction tube 313 is connected to the upstream side flow path port of the unillustrated flow path described above. The invention is applicable to various valve devices such as the on-off valves 311A and 311D and the regulator 311B described above.

### INDUSTRIAL APPLICABILITY

As described above, the valve device of the invention can provide a valve device and the like including an inner disk that can be easily assembled at a predetermined position, whereby a sufficient Cv value is guaranteed and the inner disk is provided under a lower risk of being damaged, and can be suitably used for a fluid control device and a semiconductor manufacturing device.

### REFERENCE SIGNS LIST

1: valve device
10: valve body
11: first flow path
12: second flow path
13: valve chamber
14: valve chamber bottom surface
14a: valve chamber bottom surface protruding portion
14b: valve chamber bottom surface protruding portion upper surface
15: first opening
16: bonnet portion
17: bonnet portion upper portion male screw
20: inner disk
21: outer side annular portion
22: inner side annular portion
22a: upper side seat accommodating groove
22b: lower side seat accommodating groove
22c: notch
22d: outer side lower end surface
22e: inner side lower end surface
22f: gap
23: connection portion
24: second opening
25: lower side seat
25a: lower side seat lower end surface
25b: inner side bulging portion
26: upper side seat
30: press adapter
32: diaphragm presser
33: diaphragm
34: nut
35: nut lower portion female screw
36: disk
37: ball
38: stem
39: taper ring
40: lid
41: lid male screw
42: nut upper portion female screw
43: bonnet upper portion male screw
50: lower side casing
51: lower side casing male screw
52: O ring
53: lower portion casing female screw
60: upper side casing
61: spring coil
62: operation gas supply port
63: O ring
64: operation gas passage
65: first piston
66, 67, 68: O ring
69: second piston
70: O ring
71: upper side casing lower portion female screw
72: bulk head
300: semiconductor manufacturing device
301: process gas supply source
302: gas box
303: tank
304: control unit
305: process chamber
306: exhaust pump
311A: on-off valve (two-way valve)
311B: regulator
311C: pressure gauge
311D: on-off valve (three-way valve)
311E: mass flow controller
312: flow path block
313: introduction tube

1. A valve device comprising:
a valve body forming a first flow path and a second flow path that are fluid passages and a valve chamber that communicates with the first flow path and the second flow path;
an inner disk including an inner side annular portion that is disposed in a periphery of a first opening opened in the valve chamber at an edge end of the first flow path, an outer side annular portion that is disposed on an outer circumference side of the inner side annular portion, and a connection portion that has a plurality of second openings that communicate with the second flow path and connects the inner side annular portion with the outer side annular portion;
a diaphragm coming into contact with and separated from an annular upper side seat provided at an upper end portion of the inner side annular portion to cause interruption and communication between the first flow path and the second flow path, the diaphragm having a lower surface circumference edge portion that comes into contact with an upper surface of the outer side annular portion, the diaphragm having an upper surface circumference edge portion pressed downwardly by a press adapter to make the diaphragm disposed under pressure; and
an annular lower side seat provided at a lower end portion of the inner side annular portion and coming into close contact with a valve chamber bottom surface that is a bottom surface of the valve chamber, wherein
an annular valve chamber bottom surface protruding portion that is an upwardly protruding circumference edge portion of the valve chamber bottom surface on the first opening side comes into close contact with a part of a lower side seat lower end surface that is a lower end surface of the lower side seat.

2. The valve device according to claim 1, wherein the lower side seat is held in a lower side seat accommodating groove formed in an end surface of the inner side annular portion on the valve body side.

3. The valve device according to claim 1, wherein a gap to accommodate a bulging portion of the lower side seat made when the diaphragm is disposed under pressure by the press adapter is provided between an upper surface of the valve chamber bottom surface protruding portion and a lower end surface of the inner side annular portion.

4. A fluid control device comprising a plurality of fluid devices arranged from an upstream side to a downstream side, characterized in that
the plurality of fluid devices include the valve device according to claim 1.

5. A flow rate control method using the valve device according to claim 1 for adjusting a flow rate of a fluid.

6. A semiconductor manufacturing device using the valve device according to claim 1 for controlling a process gas in a process for manufacturing a semiconductor device that requires a processing step using the process gas in a closed chamber.

7. A semiconductor manufacturing method using the valve device according to claim 1 for controlling a flow rate of a process gas in a process for manufacturing a semiconductor device that requires a processing step using the process gas in a closed chamber.

8. The valve device according to claim 2, wherein a gap to accommodate a bulging portion of the lower side seat made when the diaphragm is disposed under pressure by the press adapter is provided between an upper surface of the valve chamber bottom surface protruding portion and a lower end surface of the inner side annular portion.

9. A fluid control device comprising a plurality of fluid devices arranged from an upstream side to a downstream side, characterized in that
the plurality of fluid devices include the valve device according to claim 2.

10. A fluid control device comprising a plurality of fluid devices arranged from an upstream side to a downstream side, characterized in that
the plurality of fluid devices include the valve device according to claim 3.

11. A fluid control device comprising a plurality of fluid devices arranged from an upstream side to a downstream side, characterized in that
the plurality of fluid devices include the valve device according to claim 8.

12. A flow rate control method using the valve device according to claim 2 for adjusting a flow rate of a fluid.

13. A flow rate control method using the valve device according to claim 3 for adjusting a flow rate of a fluid.

14. A flow rate control method using the valve device according to claim 8 for adjusting a flow rate of a fluid.

15. A semiconductor manufacturing device using the valve device according to claim 2 for controlling a process gas in a process for manufacturing a semiconductor device that requires a processing step using the process gas in a closed chamber.

16. A semiconductor manufacturing device using the valve device according to claim 3 for controlling a process gas in a process for manufacturing a semiconductor device that requires a processing step using the process gas in a closed chamber.

17. A semiconductor manufacturing device using the valve device according to claim 8 for controlling a process gas in a process for manufacturing a semiconductor device that requires a processing step using the process gas in a closed chamber.

18. A semiconductor manufacturing method using the valve device according to claim 2 for controlling a flow rate of a process gas in a process for manufacturing a semiconductor device that requires a processing step using the process gas in a closed chamber.

19. A semiconductor manufacturing method using the valve device according to claim 3 for controlling a flow rate of a process gas in a process for manufacturing a semiconductor device that requires a processing step using the process gas in a closed chamber.

20. A semiconductor manufacturing method using the valve device according to claim 8 for controlling a flow rate of a process gas in a process for manufacturing a semiconductor device that requires a processing step using the process gas in a closed chamber.
